(19) United States
(12) Patent Application Publication
(10) Pub. No.: US 2014/0041904 A1
(43) Pub. Date: Feb. 13, 2014

(54) METHOD FOR MAKING A TWO-LAYER CAPACITIVE TOUCH SENSOR PANEL

(71) Applicant: James Pedder, Oxford (GB)

(72) Inventor: James Pedder, Oxford (GB)

(73) Assignee: M-SOLV LIMITED, Kidlington, Oxford (GB)

(21) Appl. No.: 13/984,554

(22) PCT Filed: Feb. 10, 2012
(86) PCT No.: PCT/GB2012/000134

§ 371 Date: Oct. 11, 2013

(30) Foreign Application Priority Data
Feb. 11, 2011 (GB) 1102412.2

(51) Int. Cl. H05K 3/46; H05K 1/02

(52) U.S. Cl. CPC H05K 3/4644; H05K 1/0298
USPC 174/251; 427/79; 427/555

(57) ABSTRACT

A method of fabricating a two-layer capacitive touch sensor panel comprising the following steps: a) depositing a first transparent electrically conductive layer on a transparent cover sheet; b) forming a pattern in the transparent electrically conductive layer to create a first set of discrete electrode structures; c) depositing a transparent dielectric layer over the discrete electrode structures; d) depositing a second transparent electrically conductive layer onto the transparent dielectric layer; e) forming a pattern in the transparent electrically conductive layer to create further discrete electrode structures by laser ablation, this pattern either not penetrating or penetrating only part way through the dielectric layer so as to avoid damaging the first set of discrete electrode structures; f) forming electrical connections or vias between the two transparent electrically conductive layers through the dielectric layer; and g) forming electrical connections between the transparent electrically conductive layer(s) and an electrical track or busbar formed at the periphery of the panel.) The method provides a maskless, chemical free way to fabricate a two-layer “cover integrated” sensor. A two-layer capacitive touch sensor panel fabricated by this method is also described

### TECHNICAL FIELD

This invention relates to a method of making a two-layer capacitive touch sensor panel and to a panel made by the method.

### BACKGROUND ART

### Background

There is a great desire to incorporate capacitive touch sensors with multi touch capability into hand held devices such as mobile smart phones, MP3 players, PDAs, tablet PCs, etc. Such devices generally have a transparent front cover sheet that is made of glass or plastic onto the rear of which a two-layer transparent capacitive sensor is bonded. Such a “dual component” arrangement can lead to a cover/sensor module that is undesirably thick and heavy. To reduce the thickness and weight it is desirable to form the sensor directly on the cover sheet. This “cover integrated” sensor arrangement leads to a module that is substantially thinner than can be made by other means

Prior art in the “dual component” area generally involves making a two-layer capacitive sensor and cover sheet as separate items and then laminating them together. Both the cover sheet and the substrate for the sensor can be made of either glass or plastic. In one case, the two transparent electrically conducting layers (TCLs) of the sensor are deposited and patterned on the opposite faces of a transparent glass or plastic substrate which is then laminated to the cover sheet with an ultra violet (UV) or thermally curing transparent adhesive. In another case, one of the TCLs of the sensor is formed on the rear face of the cover sheet and the other TCL is formed on one side of a separate transparent substrate. This substrate is subsequently laminated to the rear of the cover sheet with its TCL either on the cover side or on the opposite (lower) side. Both of these manufacturing technologies lead to a cover/sensor module that is relatively thick and heavy because it consists of two components.

Prior art in the “cover integrated” area involves sequentially depositing a first TCL, a dielectric layer and a second TCL on the cover sheet. Both first and second TCLs are patterned to create discrete electrode structures. Patterning of the TCLs is generally carried out using lithography processes involving application of resist, exposure through a mask, resist development, chemical etching of the TCL and finally resist stripping. Such multi-step processes which have to be repeated for every material layer requiring patterning have a high cost associated with them as large quantities of capital equipment are needed and large amounts of chemicals are required. A major factor contributing to the high cost of ownership is that for each sensor design special costly masks are required for every layer to be patterned.

The present invention seeks to provide an improved method of fabricating a “cover integrated” two-layer capacitive touch sensor panel which significantly reduces, and in some cases eliminates, the use of chemical etching so reducing or avoiding the above problems, thereby simplifying the fabrication of such panels and reducing their cost.

### DISCLOSURE OF INVENTION

According to a first aspect of the invention, there is provided a method of fabricating a two-layer capacitive touch sensor panel comprising the following steps:
(a) depositing a first transparent electrically conductive layer on a transparent cover sheet;
(b) forming a first pattern in the first transparent electrically conductive layer to create a first set of discrete electrode structures therein;
(c) depositing a transparent dielectric layer over the first discrete electrode structure of the first transparent electrically conductive layer;
(d) depositing a second transparent electrically conductive layer onto the transparent dielectric layer;
(e) forming a second pattern in the second transparent electrically conductive layer to create a second set of discrete electrode structures therein by laser ablation, the second pattern not penetrating or penetrating only part way through the dielectric layer so as not to damage the first set of discrete electrode structures;
(f) forming electrical connections or vias between the first and second transparent electrically conductive layers through the dielectric layer; and
(g) forming electrical connections between the first and/or second transparent electrically conductive layer and an electrical track or busbar formed at or adjacent the periphery of the panel.

According to another aspect of the invention there is provided a two-layer capacitive touch sensor panel comprising:
a transparent cover sheet;
a first transparent electrically conductive layer deposited on the transparent cover sheet;
a first pattern in the first transparent electrically conductive layer providing a first set of discrete electrode structures therein;
a transparent dielectric layer deposited over the first discrete electrode structure of the first transparent electrically conductive layer;
a second transparent electrically conductive layer deposited onto the transparent dielectric layer;
a second pattern in the second transparent electrically conductive layer formed by laser ablation to create a second set of discrete electrode structures therein, the second pattern not penetrating or penetrating only part way through the dielectric layer so as not to damage the first set of discrete electrode structures;
electrical connections or vias between the first and second transparent electrically conductive layers through the dielectric layer; and
electrical connections between the first and/or second transparent electrically conductive layer and an electrical track or busbar formed at or adjacent the periphery of the panel.

The term ‘transparent dielectric layer’ as used herein should be understood to include any transparent layer of insulating material that can be deposited to form such a layer.

A preferred form of the invention provides a novel maskless, chemical free way to make a two-layer “cover integrated” sensor. All electrode patterning and all necessary electrical interconnections between TCLs are carried my means of direct write laser processes. In a first step, a first TCL is deposited on the cover sheet which is directly laser patterned in a second step to form one electrode layer of the sensor. Following this, in a third step, the dielectric layer that separates the two electrode layers is then deposited on top of the patterned first TCL. In a fourth step, a second TCL is deposited on top of the dielectric.

This second TCL is laser patterned in a fifth step to form the other sensor electrode so forming the capacitive sensor.

Electrical connections must be made to the electrodes on both first and second TCLs and it is convenient to do this on one rather than two-layers. An important feature of the invention involves the use of laser processes to form electrical interconnects or vias through the dielectric layer and, if necessary, through decorative ink provided around the border of the panel such that independent electrical connections to both TCLs can be made at one level (usually the upper level) in the stack of materials and that such connections can be hidden by the decorative border ink.

Key steps of a preferred form of the method are:
1) First TCL deposited directly on cover sheet
2) First TCL patterned by laser ablation
3) Transparent dielectric layer, preferably with thickness in range 1 to 10 μm, deposited on top of patterned first TCL
4) Second TCL (using same or different material to first TCL) deposited on top of dielectric layer
5) Second TCL patterned by laser ablation, without fully penetrating dielectric layer and without causing damage to first TCL
6) Electrical connections or vias formed through dielectric by one of the following methods:
   a. after dielectric layer deposition (step 3 above), using a pulsed laser to drill through the dielectric layer at the location where vias are required. Subsequent deposition of second TCL (at step 4) then makes electrical connection between the TCL layers. The process whereby the laser drills through the dielectric and stops on the first TCL is such that either
      i. full penetration of the first TCL does not occur or
      ii. penetration of the first TCL occurs but sufficient of the first TCL material is left in an annulus at the bottom of the via hole to allow an electrical connection to be subsequently made when the second TCL is applied
   b. before the dielectric layer is applied to the patterned first TCL (before step 3 above), apply a thin layer of material in the specific locations where vias are required. After deposition of the dielectric layer, a pulsed laser beam is then directed to the via locations. The wavelength of the pulsed laser and the optical absorption characteristics of the material deposited under the dielectric at the via locations are selected such that the radiation passes without significant absorption through the dielectric and is strongly absorbed in the deposited material. The absorption of laser energy by the locally deposited material is such as to raise the temperature of the material and cause it to expand and explosively detach from the first TCL so removing a section of the dielectric in the expansion process. The first TCL below the absorbing material is undamaged in this process or sufficient of the first TCL material is left in an annulus at the bottom of the via hole to allow an electrical connection to be subsequently made when the second TCL is applied. Subsequent deposition of second TCL at step 4 then makes electrical connection between the TCL layers, or
   c. after the second TCL has been deposited (before either step 4 or 5 above), direct a laser beam at the locations where vias are required, the characteristics of the laser beam in terms of wavelength, pulse length, power or energy density being such that the materials of the second TCL, the dielectric and the first TCL are melted and displaced such that a local electric connection is made from the second TCL through the dielectric layer to the first TCL. Such a laser process may be described as a “fusing” process.

The invention thus provides a method of fabricating a “cover integrated” two-layer capacitive touch sensor panel that is much less complex than known lithographic processes and hence, more reliable and less expensive than known processes.

The invention also enables much finer patterning to be reliably carried out and enables electrical connections or vias to be formed as well as electrical tracks or busbars and their connection to the TCLs to be fabricated in a relatively simple manner.

A further advantage of the invention is that it enables a very thin dielectric layer to be used, eg having a thickness of only 10s of μms. In a preferred arrangement, the dielectric layer may have a thickness off 10 μm or less. This further reduces the thickness and weight of the sensor panel.

Other preferred and optional features of the invention will be apparent from the following description and from the subsidiary claims of the specification.

### BRIEF DESCRIPTION OF DRAWINGS

An embodiment of the present invention will now be described by way of example, with reference to the accompanying figures in which:

FIG. 1 shows the construction of a first known type of cover/sensor module as used in many hand held devices with capacitive touch capability;

FIG. 2 shows detail of the construction of the type of sensor 1 shown in FIG. 1;

FIG. 3 shows the construction of another known type of cover/sensor module where one of the TCLs of the sensor is applied to the cover and the other is applied to a separate substrate;

FIG. 4 a two-layer conductive sensor panel fabricated by a method according to the invention;

FIG. 5 shows diagrammatically the steps by which the cover/sensor module of FIG. 4 is fabricated according to a preferred method of the invention;

FIG. 6 shows one method for forming electrical interconnects between the first and second TCLs through the dielectric layer in order to allow external electrical connections to be made on a single level;

FIG. 7 shows an alternative method for forming electrical interconnects between the first and second TCLs through the dielectric layer;

FIG. 8 shows a variation on the laser beam absorbing layer LBAL based method for forming electrical interconnects between the first and second TCLs through the dielectric layer in order to allow external electrical connections to be made on a single level;

FIGS. 9 and 10 show another proposed method for forming electrical interconnects between the first and second TCLs through the dielectric layer in order to allow external electrical connections to be made on a single level;

FIG. 11 shows a laser process that can be used to bring the electrical connections from the TCLs to busbars that are located on top of a decorative border ink;

FIG. 12 shows another laser process that can be used to bring the electrical connections from the TCLs to busbars on top of a decorative border ink; and

FIG. 13 shows another possible laser process that can be used to bring the electrical connections from the TCLs to busbars on top of a decorative black border ink.

### DESCRIPTION OF PREFERRED EMBODIMENTS

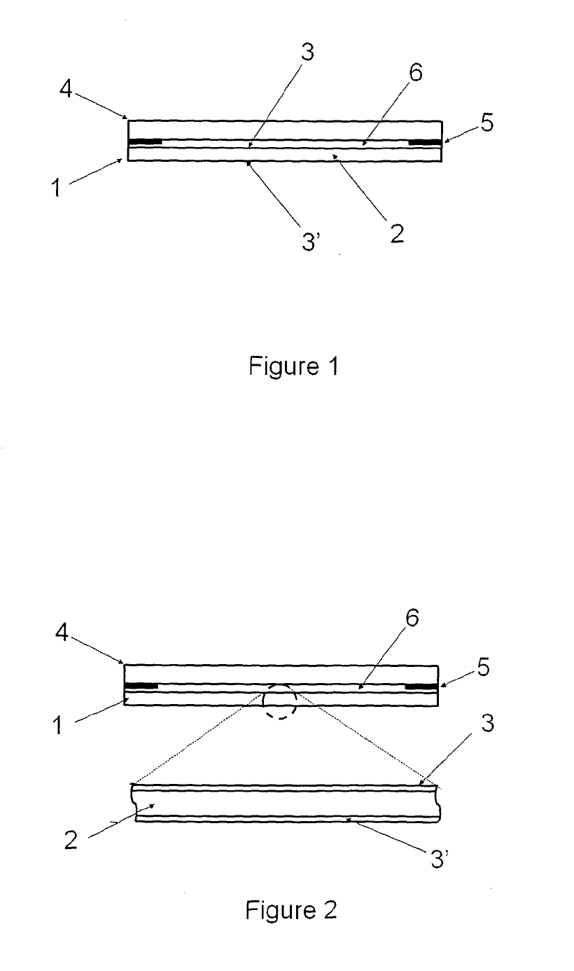

FIG. 1: This shows the construction of a first known type of cover/sensor module as used in many hand held devices with capacitive touch capability. Capacitive sensor 1 is of a two-layer type and consists of a transparent dielectric material 2 such as plastic or glass with a transparent conducting layer (TCL) on each side 3, 3′. Electrode patterns are formed in the TCLs to create the capacitive sensor. Cover sheet 4 is made of either glass or plastic and may have decorative ink 5 applied around the border. The capacitive sensor 1 is generally bonded to the cover sheet glass by means of UV curing glue 6 that fills the gap between the cover sheet 4 and the sensor,

FIG. 2: This shows the detail of the construction of the type of sensor 1 shown in FIG. 1. The dielectric substrate 2 for the capacitive sensor is generally made of glass or plastic. In the case of a glass substrate the thickness is generally in the range 0.33 to 0.7 mm. In the case of a plastic substrate the thickness is less, in the 0.1 to 0.3 mm range. The TCLs 3, 3′ may be of organic or inorganic type. Indium Tin oxide (ITO) is a very commonly used inorganic TCL. The TCLs are applied to opposite faces of the sensor substrate 2 by physical vapour deposition (PVD) or solution based deposition processes. One side of the sensor may also have a metal layer applied in some areas of the border to give an enhanced conductivity to electrical tracks (busbars) connecting to the sensor electrodes on that side. Patterning of the TCLs 3,3′ to form the sensor electrodes and the metal busbars is generally carried out by standard lithographic processes. After forming, the sensor is aligned to and laminated to the cover sheet 4 by means a UV or thermally curing transparent glue 6. A border 5 of decorative ink is also usually provided to conceal the electrical tracks.

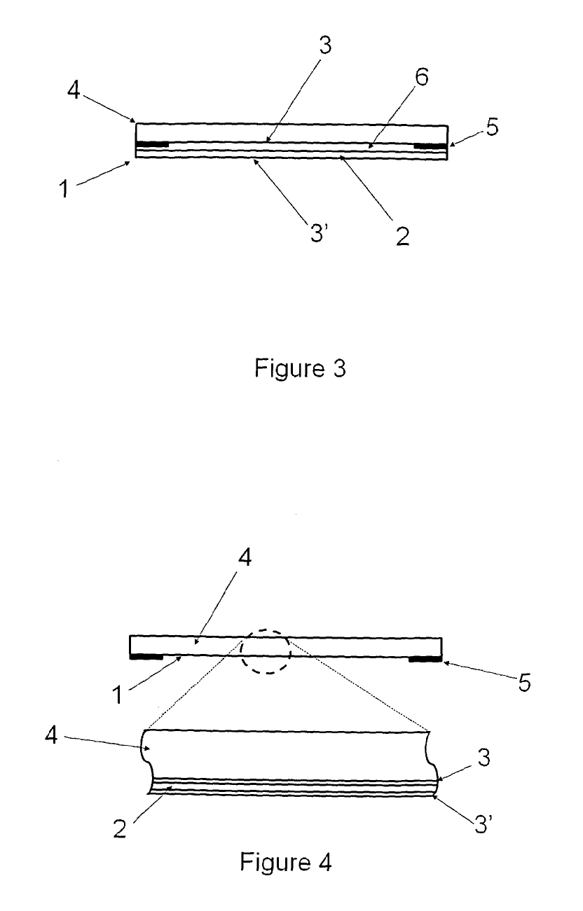

FIG. 3: This shows the construction of another known type of cover/sensor module where one 3 of the TCLs of the sensor is applied to the cover 4 and the other 3′ is applied to a separate substrate 2. Cover sheet 4 has a TCL 3 deposited on its lower face. This TCL is patterned to form one set of sensor electrodes. Sensor dielectric substrate 2, which may be made of glass but is more likely to be made of plastic, has a TCL 3′ deposited on one face. This TCL is patterned to form the other sensor electrode set. The sensor substrate 2 is laminated to the cover sheet 4 by means of a transparent UV or thermally curing glue 6. The sensor substrate 2 may be attached to the cover sheet 4 with the TCL 3′ on the side facing the cover sheet 4 so that the glue alone forms the dielectric separating the 2 sensor electrode sets. Alternatively, the sensor substrate 2 may be attached to the cover sheet 4 with the TCL 3′ on the side away from the cover sheet 4 (as shown in FIG. 3) such that the dielectric material separating the 2 sensor electrodes consists of two-layers, the sensor substrate 2 and the glue 6.

FIG. 4: This shows a two-layer conductive sensor panel fabricated by a method according to the invention. The lower part of the figure shows the construction of the panel in greater detail. Cover sheet 4 is made plastic or glass. Glass with a thickness of about 0.8 mm is suitable. A two layer capacitive sensor 1 consisting of first TCL layer 3, thin dielectric layer 2 and second TCL 3′ is formed directly on the cover sheet 4.

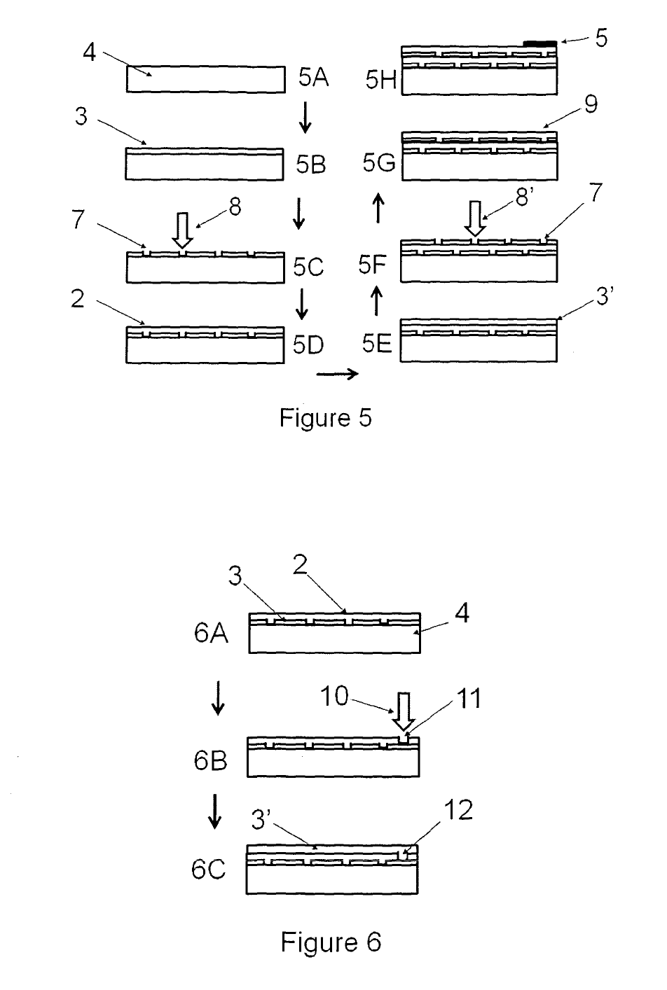

FIG. 5: This shows diagrammatically the steps by which the cover/sensor module of FIG. 4 is fabricated according to a preferred method of the invention. In the figure, the underside of the cover substrate 4 on which the sensor is constructed is shown facing upwards. FIG. 5A shows the cover sheet 4 which can be glass or plastic. Some candidate plastic materials are polyethylene terephthalate (PET), polymethylmethacrylate (PMMA acrylic) or polyethylene naphthalate (PEN). Typical thickness for glass covers may be in the range 0.4 to 1.1 mm. If the cover is made of plastic, thicknesses in the range 0.1 to more than 1 mm are possible. FIG. 5B shows the deposition of first TCL 3 on the top side of cover sheet 4. This layer may be an inorganic or organic transparent conducting material and can be applied by PVD or solution based processes. Indium Tin Oxide (ITO) is a suitable inorganic material for TCL 3. Typically, this is applied by a PVD process (sputtering) but other methods are possible. For capacitive touch sensor use, the TCLs are required to be highly transparent (T>90%) in the visible region and have a surface resistivity in the range 50 to 200 ohms/square. Other inorganic materials can be used as the TCL. These include Aluminium doped Zinc Oxide (AZO), Indium Zinc oxide (IZO), Tin Oxide (SnO2), fluorine doped Tin Oxide (FTO) or electrides (eg 12CaO.7Al2O3). Candidate organic TCL materials are poly3,4-ethylenedioxythiophene (PEDOT) and polyaniline. It is also possible to use TCL materials based on graphene, carbon nano-tubes or metal nano-wires. TCL thicknesses are generally in the sub micron range. For example, a TCL of ITO with surface resistivity around 100 ohm/square, generally has a thickness in the 25 to 50 nm range.

FIG. 5C shows the process whereby discrete, separated electrode structures are formed in the first TCL 3 by creating narrow electrically conducting breaks 7 in the layer. This step may be performed by a conventional lithographic and chemical etching process but in the preferred embodiment of the method this electrode formation step is carried out by ablating grooves 7 through the TCL using a laser beam 8. By using a focused laser beam, grooves with widths in the range from below 10 μm to several 10s of μm are readily created. Such Narrow grooves (eg 10 μm wide or less) have the advantage of being difficult to be observed by a user of the device in which the sensor is mounted. An advantage provided by the method described herein is that grooves 10 μm wide or less can be readily formed by laser ablation. Such narrow grooves are difficult to form reliably by lithographic and etching processes.

Since the TCL is backed only by a transparent glass or plastic substrate, it is possible to use a variety of lasers for forming the grooves. Pulsed Diode-pumped solid-state (DPSS) lasers operating at infra red (IR) (1064 nm) and UV (355 nm) wavelengths are likely to be most effective but lasers operating at other wavelengths such as 532 nm or 266 nm can also be used.

In general, pulse energy densities in the range 1 to a few Joules per cm2 and a few laser shots are sufficient to remove all the TCL material without damage to the underlying material of the cover 4. In practice, the laser beam is moved continuously over the surface of the TCL tracing out a path that defines the electrode structures required. The laser pulse repetition rate and speed of the beam are controlled so that each area receives the necessary number of laser pulses.

FIG. 5D shows the step whereby the dielectric layer 2 that separates the two electrode layers of the sensor is deposited on top of the first, patterned TCL 3. This dielectric layer can be of organic or inorganic material and can be of any reasonable thickness but it is a preferred embodiment of this invention that the layer is very thin, eg only having a thickness of 10s of μm. In a preferred arrangement, the dielectric layer may have a thickness in the range 1 to 10 μm. The dielectric layer 2 must be highly transparent in the visible region. There are many candidate organic materials for the dielectric layer. Examples are PMMA (acrylic), polycarbonate, various resists, lacquers or inks, BCB (bisbenzocyclobutene—Dow “cyclotene”), etc. Coating methods for the organic material include spinning, dipping, die slot coating and PVD.

There are also many candidate inorganic materials for the dielectric layer. These include SiO2 (silicon dioxide), Al2O3 (aluminium oxide), phosphosilicate glass, etc. Application may be by PVD or in some cases by spinning or dipping.

FIG. 5E shows the deposition of the second TCL 3′ on the top of dielectric layer 2. This TCL may be of the same material as the first TCL or, alternatively, it may a different material. The characteristics of this second TCL in terms of resistivity and transparency are similar to the first TCL.

FIG. 5F shows the process whereby discrete, separated electrode structures are formed in the second TCL 3′ by creating electrically conducting breaks 7 in the layer. In general the electrodes formed in the second TCL 3′ are arranged at right angles to the electrodes formed in the first TCL 3. This second TCL electrode formation step is carried out by ablating grooves through the second TCL using a laser beam 8′. This laser can be of the same type and wavelength as used to structure the first TCL or alternatively it may have a different wavelength or different characteristics in terms of pulse duration.

An important characteristic of the laser ablation process of the second TCL 3′ is that it removes all the second TCL material completely forming narrow electrically separating grooves in the second TCL either without removal of any of the dielectric layer 2 below or removing some of the dielectric layer 2 but without penetrating it fully so as to expose or damage the first TCL 3 below.

It is also important that the laser beam used to pattern the second TCL 3′ does not cause any visible or electrical damage to the first TCL 3 below the dielectric 2. To achieve this last result it is important that either:
1) if the dielectric layer 2 is highly transparent to the laser radiation used to pattern the second TCL 3′, then the energy density required to laser ablate the material of the second TCL 3′ for a given wavelength must be significantly lower than that required to ablate the material of the first TCL. Such a case occurs if a laser with a near infra-red wavelength of around 1064 nm is used to pattern the second TCL and the dielectric layer is made of SiO2 or Al2O3 which are very transparent at this wavelength. In such a case, the required difference in ablation energy densities between the first TCL and the second TCL can be achieved by using different materials for the two TCLs (eg ITO for the first TCL and AZO for the second TCL) or by using the same material deposited using different processes. It has been found that ITO deposited at high temperature used as the first TCL has a higher ablation energy density to a layer of ITO deposited at low temperature as the second TCL or
2) if the dielectric layer material is such that it partially or significantly absorbs the laser beam used to pattern the second TCL, then the energy density of the laser beam when it strikes the first TCL is attenuated to a value below the ablation energy density of the first TCL. Such a situation arises when a laser operating in the UV (eg 355 nm) or DUV (eg 266 nm) is used to pattern the second TCL and dielectric materials such as BCB, resists, lacquers or ink are used

FIG. 5G shows an optional step whereby a second dielectric layer 9 is deposited on top of the second TCL 3′ after laser patterning in order to encapsulate it to protect the second TCL 3′ from damage. The dielectric used may be of inorganic or organic type. The thickness of this upper dielectric layer 9 may be arranged such that it acts as an anti-reflection coating to reduce reflection of light at the sensor-air interface.

FIG. 5H shows a final step where decorative ink 5 is applied on top of the encapsulation layer 9 in a border region of the module. The decorative ink 5 may be applied at various earlier stages in the manufacture of the cover sensor. It can be applied on the cover substrate 4 before the first TCL 3 is deposited, on the first TCL 3 before the dielectric 2 is deposited, on the dielectric 2 before the second TCL 3′ is deposited or on the second TCL 3′ before the encapsulation layer 9 is deposited. In these cases, all material layers deposited after the decorative border ink 5 is applied cover the main sensor area and the sensor area covered by the decorative border.

FIG. 6: This shows one method for forming electrical interconnects between the first and second TCLs through the dielectric layer in order to allow external electrical connections to be made on a single level.

FIG. 6A shows the sensor module at the stage when the cover substrate 4 has been coated with first TCL 3 which has then been laser patterned to form electrodes and then over-coated with dielectric layer 2. This corresponds to the state of the sensor module after step D in FIG. 5.

FIG. 6B shows the next step where a pulsed laser 10 is used to drill through the dielectric layer to create a hole (or via) 11. This process is performed at all the locations where vias are required. In general, such vias are required to have sizes from several 100 microns down to a few 10s of microns. It is important that the dielectric layer material 2 is fully removed to expose the first TCL 3 and it is also important that the laser drilling process does not damage the first TCL 3 to such an extent that electrical connection to it through the via created in the dielectric layer is compromised. Partial ablation of the first TCL 3 over the whole of the area at the bottom of the via hole is acceptable and it is also acceptable that some of the first TCL 3 is removed from the cover substrate 4 so long as sufficient of the first TCL material 3 is left in an annular region at the bottom of the via hole to allow an electrical connection to be subsequently made when the second TCL 3′ is applied.

The choice of optimum laser for this process is made based on the different optical characteristics of the materials of the dielectric layer 2 and the first TCL 3 and also the cover substrate 4. The objective is to achieve a situation where the laser ablation threshold of the dielectric is much lower than that of the first TCL 3. Generally, this naturally arises when the laser wavelength is such that the beam is strongly absorbed in the dielectric material 2 and is not absorbed significantly in the first TCL material 3. It can also occur when both TCLs absorb the laser energy but the vapourization temperature of the dielectric layer 2 is much lower than the vapourization temperature of the first TCL 3. This is generally the case when the dielectric is an organic material and the first TCL 3 and substrate 4 below are both inorganic materials. A pulsed laser with a wavelength of 355 nm has been found to be effective in creating vias through a cyclotene layer of about 2 μm thickness without significantly damaging a first TCL 3 made of 0.1 mm ITO deposited on a glass cover.

FIG. 6C shows the final step needed to complete the electrical interconnection process. Second TCL 3′ is deposited on top of the dielectric layer 2 and in areas 11 where the dielectric layer 2 has been previously removed the second TCL 3′ material fills the via and makes an electrically conducting path 12 between the first and second TCLs.

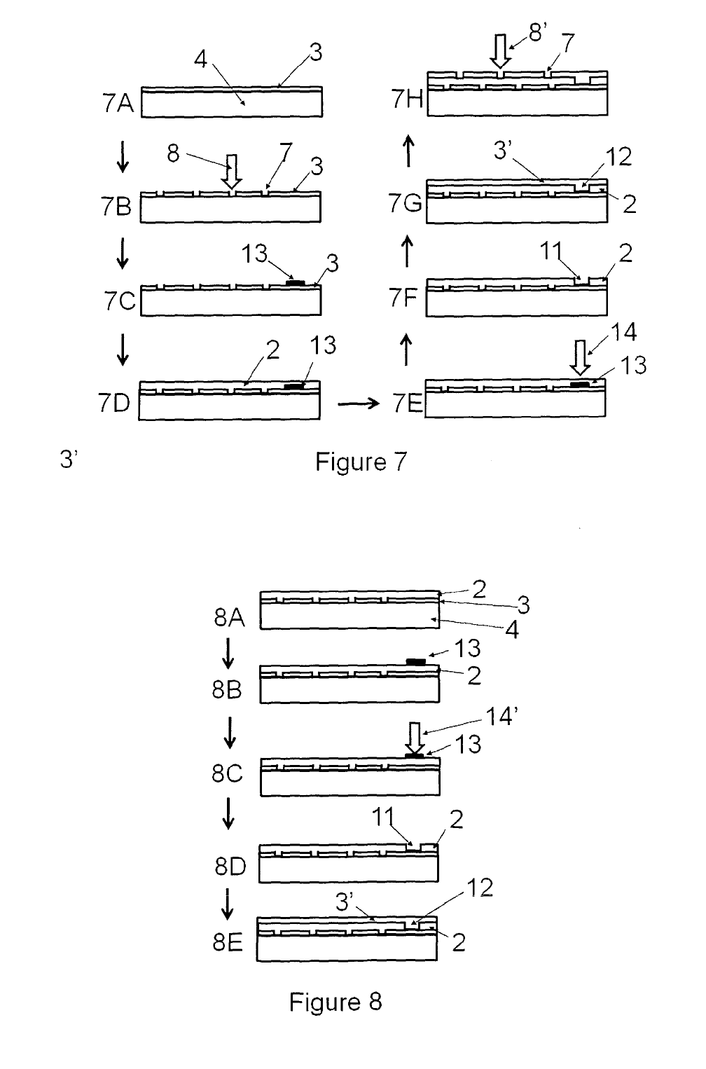

FIG. 7: This shows an alternative method for forming electrical interconnects between the first and second TCLs through the dielectric layer in order to allow external electrical connections to be made on a single level. FIG. 7A shows the sensor cover substrate 4 onto which a first TCL 3 has been deposited. FIG. 78 shows the step whereby a laser beam 8 is used to form grooves 7 in the first TCL 3 to divide it into electrically separated electrodes. FIG. 7C shows the next step where a laser beam absorbing layer (LBAL) 13 is deposited on top of the first TCL 3 locally at the sites where vias through the dielectric are required. The subsequent step where the dielectric layer 2 is deposited on top of the first TCL 3 and the sites where the LBAL 13 has been deposited is shown in FIG. 7D.

FIGS. 7E and 7F show the laser process that follows. Pulsed laser beam 14 is directed to the surface of the dielectric 2 where the LBAL has been applied and where the vias are required. The laser wavelength is chosen such that some significant fraction of the laser pulse energy is transmitted through the dielectric layer 2 and is absorbed by the LBAL material which is heated, expands and becomes detached from the first TCL 3 and explodes upwards. The upward expanding LBAL 3 causes the section of dielectric layer 2 immediately above it to be lifted and to be separated from the rest of the dielectric layer 2. The LBAL material is completely removed by the laser expansion process so a hole (via) 11 through to the first TCL 3 is formed.

FIG. 7G shows the next step where the second TCL 3′ is deposited on top of the dielectric layer 2 and into the via holes 11 where the dielectric layer has been removed. The second TCL material 3 fills the via hole and makes an electrically conducting path 12 between the first and second TCLs. Ideally the first TCL 3 around the site of the via hole is completely unperturbed during this LBAL based laser ablation process but it is also acceptable that some of the first TCL 3 is removed from the cover substrate 4 so long as sufficient of the first TCL material 3 is left in an annular region at the bottom of the via hole to allow an electrical connection to be subsequently made when the second TCL 3 is applied.

For the above laser process to be most effective, the laser energy density needed to cause the LBAL 13 to heat, expand and detach from the first TCL 3 should be significantly lower than the energy density needed to vapourize the first TCL 3.

Finally, as shown in FIG. 7H, laser 8′ is used to create grooves 7 in the second TCL 3 to form the top sensor electrode pattern.

FIG. 8: This shows a variation on the LBAL based method discussed above for forming electrical interconnects between the first and second TCLs through the dielectric layer in order to allow external electrical connections to be made on a single level. In this case, the LBAL is applied on top of the dielectric layer rather than under it as discussed above and shown in FIG. 7. FIG. 8A shows the sensor cover substrate 4 onto which a first TCL 3 has been deposited, subsequently laser patterned and then over-coated with a dielectric layer 2. FIG. 8B shows the next step where a special laser beam absorbing layer (LBAL) 13 is deposited on top of the dielectric layer 2 locally at the sites where vias through the dielectric are required.

FIGS. 8C and 8D show the laser process that follows. Pulsed laser beam 14′ is directed to the surface of the dielectric 2 where the LBAL 13 has been applied and where the vias are required. The wavelength of the laser is selected such that the pulse energy is strongly absorbed by the LBAL material which is rapidly heated to high temperature. Following this, thermal conduction causes the dielectric material below the heated LBAL 13 to be heated rapidly and a pressure wave to propagate downwards through the dielectric 2 towards the first TCL 3. The combination of these processes causes the perturbed dielectric material 2 to become detached from the first TCL 3 and explode upwards. The LBAL material and dielectric material below it is completely removed by this process so a hole (via) 11 through to the first TCL 3 is formed.

FIG. 8E shows the next step where the second TCL 3′ is deposited on top of the dielectric layer 2 and into the via holes 11 where the dielectric layer has been removed. The second TCL material 3 fills the via hole and makes an electrically conducting path 12 between the first and second TCLs. Ideally, the first TCL 3 around the site of the via hole is completely unperturbed during this LBAL based laser ablation process but it is also acceptable that in some of the first TCL is removed from the cover substrate so long as sufficient of the first TCL material 3 is left in an annular region at the bottom of the via hole to allow an electrical connection to be subsequently made when the second TCL 3 is applied.

If the areas where vias are required are outside the viewable area of the sensor (eg behind the bezel of the device), relatively large areas can be coated with LBAL material and in this case the size of the laser focal spot used to vapourize the LBAL defines the size of the via created since only the area of LBAL exposed to the laser radiation will be vaporized. Alternatively, if the vias are required in areas of the sensor that can be viewed then it is preferable that the LBAL material is deposited over smaller areas that correspond to the required via size. In this case, the laser beam size can be greater than the required via size and can overlap the area of deposited LBAL material as the area where LBAL material is deposited will be selectively heated and so form a via corresponding in size to the LBAL area rather than the laser spot size.

Preferred lasers for this LBAL based process of via formation are of pulsed type with pulse durations less than a few 100 ns and with wavelengths from infa-red (IR) to ultra-violet (UV). Pulsed diode-pumped solid state (DPSS) lasers operating at 1064, 532 and 355 nm are particularly appropriate. With some combinations of LBAL, dielectric and first TCL materials, the via formation process may require only a single laser pulse. Such a single laser shot process is preferred as it is fast, can be performed on the fly (ie with laser beam moving) and is less likely to cause damage to the first TCL.

There are particular requirements for the LBAL material as follows:
1) It should be of a material that is strongly absorbing to radiation from a pulsed laser,
2) It can be conveniently deposited in local areas
3) It can be deposited as a very thin layer

The material of the LBAL can be organic, inorganic or metallic and can be deposited by many appropriate methods. If deposited by evaporative methods then subsequent steps to localize it are required. Hence, it is preferred that the LBAL is deposited by means of an ink jet printing process since this allows controlled selective deposition in areas as small as a few 10s of microns. Suitable LBAL materials that can be applied by ink jet printing are:
1) Organic inks as used in the printing industry
2) Organic resists
3) Dispersions of inorganic particles
4) Dispersions of metallic particles

In all cases, it is expected that LBAL thickness will be at most a few microns.

Another preferred method, in terms of localized LBAL deposition on either the first TCL or on the dielectric layer, is to apply a thin layer of a UV or thermally curing liquid such as a resin, negative resist, decorative ink or other liquid over the full area of the sensor by such methods as spinning, dipping or slot die coating and then using a laser of suitable wavelength to UV or thermally cure the material in the local areas where vias are required. Following this curing step the uncured material is removed leaving local areas of cured LBAL remaining.

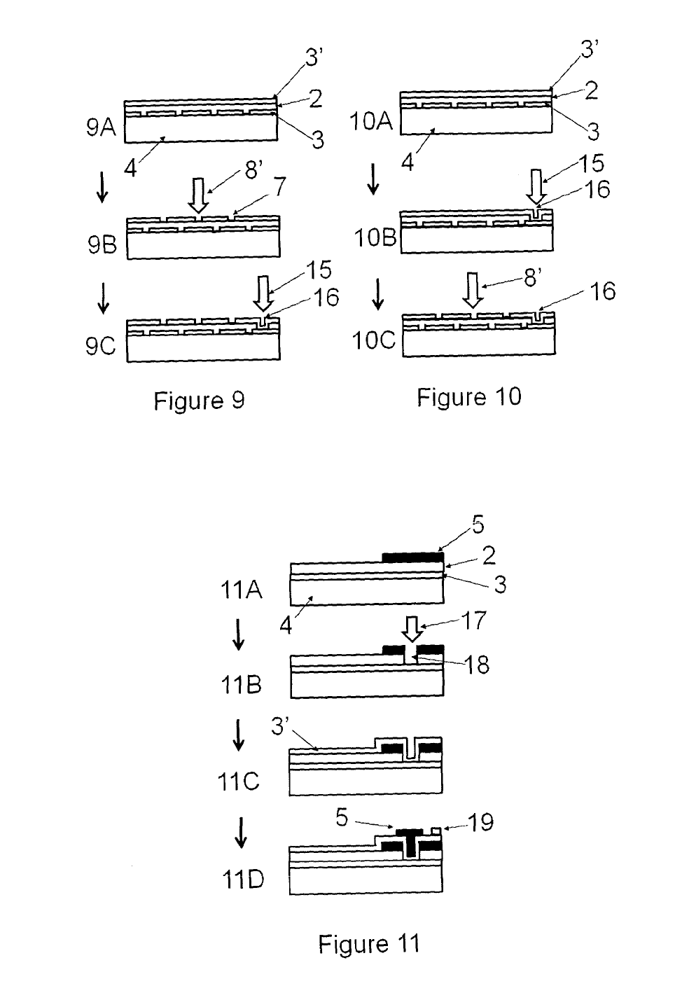

FIGS. 9 and 10 show another proposed method for forming electrical interconnects between the first and second TCLs through the dielectric layer in order to allow external electrical connections to be made on a single level. The two processes are similar but differ in the order in which steps take place. Both start (as shown in FIGS. 9A and 10A) with a substrate cover sheet 4, on top of which a first TCL 3 (that has been laser patterned), a dielectric layer 2 and a second TCL 3′ have been deposited. In FIG. 9B, laser 8′ is used to pattern the second TCL 3 to form electrodes by creating grooves 7 in the material. Following this a laser 15 is then focused and directed onto the surface of the second TCL 3 in the local area where an electrical connection between the TCLs is to be formed as shown in FIG. 9C. The characteristics of the laser beam in terms of wavelength, pulse length, power or energy density are such that the materials of the second TCL 3′, the dielectric 2 and the first TCL 3 are all melted and displaced such that melted material of the second TCL 3′ comes into direct contact with melted material of the first TCL 3 so that a local electric connection 16 is made from the second TCL 3′ through the dielectric layer 2 to the first TCL 3. Such a laser process may be described as a “laser fusing” process. Ideally, during the fusing process, the first TCL 3 is melted but then reforms as a continuous layer across the bottom of the via hole so that the area of contact between the first TCL 3 and the second TCL 3′ is maximized. It is also acceptable that when the first TCL 3 melts and reforms it does not cover the full area of the bottom of the via hole but instead creates an annular region around the bottom of the via hole to which the material of the second TCL fuses. Such a “laser fusing” process is best performed in arrangements having a thin dielectric layer, eg in the range of 0.1 to 5 μms.

In FIG. 10 this laser fusing process is shown as taking place prior to patterning of the second TCL 3′. FIG. 108 shows the use of laser 15 to fuse the second TCL to the first TCL and form an electrical connection 16. FIG. 10C shows the step where the second TCL is patterned by laser 8′ to form the sensor electrodes.

Since this fusing process is one that involves melting and displacement of materials rather than the more energetic material ablation and physical removal processes used for other via formation techniques discussed above and for TCL patterning, suitable lasers to carry out the process are likely to be of continuous wave (CW) or quasi-continuous wave (QCW) type or, if pulsed, are likely to be of low pulse energy, high repetition rate type. The local average laser power density in the focal spot on the substrate surface must be such that laser energy is deposited at a rate that does not lead to material vaporization and ejection. If the laser is pulsed the peak energy density needs to be kept well below the ablation threshold energy density of the materials used for the dielectric layer or TCLs to avoid significant material removal. The most important requirement for the laser is that it operates at a wavelength that is absorbed by one or more of the materials used for the dielectric or TCLs. Significant absorption of the radiation by the cover substrate is also a possibility. Since materials used for the dielectric layer and the TCLs are highly transmissive in the visible region candidate lasers for this fusing process are likely to operate in the Far infra-red (FIR) or UV wavelength range where absorption is higher. Specifically we expect that FIR CO2 lasers operating at a wavelength of 10.6 μm, QCW or high repetition rate UV DPSS lasers operating at a wavelength of 355 nm and also deep infra-red (DUV) DPSS lasers operating at a wavelength of 266 nm are best suited to this process.

For all first TCL to second TCL interconnection methods discussed above and shown in FIGS. 6 to 10, if the interconnect is located in an area of the cover sensor such that it can be readily seen by a user of the device then it is important that the laser process forms an interconnection structure that has the same visual appearance as the surrounding layers so that the interconnection is not readily visible to the user.

In any device incorporating a two-layer capacitive sensor there is a requirement to bring the electrical connections from the electrodes on both TCLs to a connection point that is generally at one edge of the device. Electrical tracks, sometimes referred to as busbars, are used for this purpose. For cosmetic reasons, it is important that these electrical busbars are hidden from the view of the device user and this is readily achieved in the case of “dual component” sensors as shown in FIGS. 1 and 2 by placing the busbars in such a position on the sensor substrate that, when the sensor is laminated to the cover, the busbars are hidden behind the decorative ink that has been applied to the cover sheet. This decorative ink is generally black. The requirement to hide the busbars from view behind the border ink also applies to cover integrated sensors and in addition there is a requirement to hide the via connections between TCLs and via connections from the busbars to the TCLs behind the border ink. For a cover integrated sensor achieving both of these results requires complex manufacturing processes. This can be greatly simplified by the use of lasers.

The electrical connections or busbars may also be patterned by laser rather than by lithographic processes. This greatly simplifies their fabrication in view of their non-planar form and avoids the problems associated with removal of organic resists in a lithographic process without damaging the decorative ink border (which may also be formed of an organic material).

FIG. 11 shows a laser process that can be used to bring the electrical connections from the TCLs to busbars that are located on top of a decorative border ink. FIG. 11A shows the edge of a sensor module where a first TCL 3 and a dielectric layer 2 have been applied to the cover layer 4. The electrode pattern formed in the first TCL by laser ablation is not shown in the figure. At the edge of the module a layer of ink 5 is applied to form a decorative border. FIG. 11B shows the use of a pulsed laser beam 17 to drill a hole 18 through both the ink 5 and the dielectric 2 to expose the first TCL 3. For a multi shot progressive drilling process that removes the upper two-layers completely yet leaves the lowest layer substantially intact, the pulsed laser used should ideally operate at a wavelength such that the ablation energy density level of the first TCL 3 is significantly higher than that of the decorative ink 5 and the dielectric layer 2. Such a condition is likely to occur if the laser radiation is absorbed strongly in both the decorative ink 5 and dielectric layers 2 but is very weakly absorbed in the first TCL 3 or the cover 4. The drilling process shown in FIG. 116 may also be carried out in the manner shown in FIGS. 8C and 8D where the laser energy absorbed locally in the decorative ink layer causes the ink 5 and the dielectric material 2 below to detach from the first TCL 3 to form a via hole. FIG. 11C shows the next step where the second TCL 3′ is deposited on top of the dielectric layer 2 and the decorative ink border 5. The second TCL material 3′ enters the hole through the decorative ink 5 and makes an electrical connection from the first TCL 3 to the second TCL 3′.

When viewed from the front of the cover, vias such as that shown in FIG. 11C are like to be seen very clearly as the hole in the opaque ink 5 shows as an area of different colour. To eliminate this problem a layer of decorative ink 5 of exactly the same colour as used to form the border (as in FIG. 11A) is applied over the vias to form a colour matched cap and via plug as shown in FIG. 11D. When viewed from the front of the cover the via is thus much less visible. FIG. 11D shows the next interconnection step where busbars 19 are applied on top of the decorative border to connect to the TCLs.

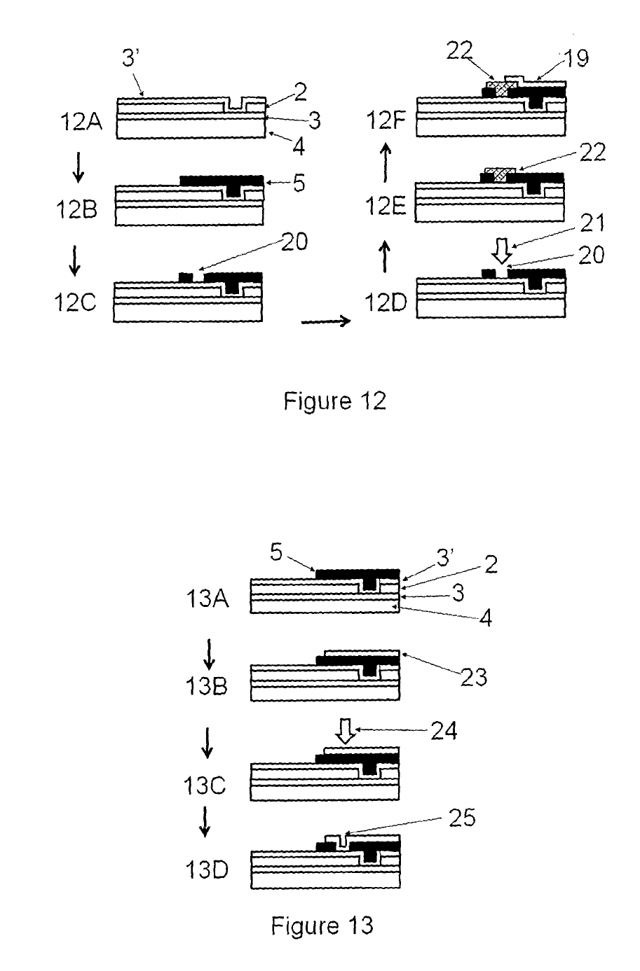

FIG. 12 shows another laser process that can be used to bring the electrical connections from the TCLs to busbars on top of a decorative border ink. FIG. 12A shows the edge of a sensor module where a first TCL 3, a dielectric layer 2 and a second TCL 3′ have been applied to the cover layer 4. Interconnecting vias between the TCLs have been made using any of the processes shown in FIG. 6, 7, 8, 9 or 10. The electrode patterns formed in the first and second TCLs by laser ablation are not shown in the figure. At the edge of the module a layer of ink 5 is applied to form a decorative border as shown in FIG. 126. It is necessary to create a via hole 20 through the layer of decorative ink 5 as shown in FIG. 12C so that an electrical connection can be made from the second TCL 3′ to busbars that will be subsequently formed on top of the border decorative ink layer 5. It is possible to create such holes during the screen or ink jet printing process during which the decorative ink is applied to the sensor, but in this case the minimum size of the holes that can be reliably and repeatably formed is generally substantially larger than required. Hence, it is preferred that the via hole through the decorative ink is formed by a laser process.

FIG. 12D shows the use of a pulsed laser beam 21 to drill a hole through the ink 5 to expose the second TCL 3′. For an effective drilling process that removes the upper ink layer 5 completely yet leaves the second TCL 3′ substantially intact, the pulsed laser used should ideally operate at a wavelength such that the ablation energy density level of the layers below the ink 5 are significantly higher than that of the decorative ink 5. Such a condition is likely to occur if the laser radiation is absorbed strongly in the decorative ink 5 but is very weakly absorbed in all layers below (the second TCL 3′, dielectric layer 2, first TCL 3 or the cover 4).

FIG. 12E shows the next step where conductive ink 22 having exactly the same colour as the decorative ink is deposited over the via holes in the decorative ink to form a colour matched electrically conducting cap and via plug. When viewed from the front of the cover 4, vias such as that shown in FIG. 12C or 12D are likely to be seen very clearly as the holes in the opaque ink show as an area of different colour. When the vias are filled with colour matched conducting ink as shown in FIG. 12E they are likely to be much less visible. Black conducting carbon ink has been found to be a good via filling material for the case where the decorative ink used is black. It is a good colour match and has satisfactory electrical properties. FIG. 12F also shows the next interconnection step where busbars 19 are applied on top of the decorative border to connect to the TCLs via the conducting ink plug 22.

FIG. 13 shows another possible laser process that can be used to bring the electrical connections from the TCLs to busbars on top of a decorative black border ink. FIG. 13A shows the edge of a sensor module where a first TCL 3, a dielectric layer 2 and a second TCL 3′ have been applied to the cover layer 4. Interconnecting vias between the TCLs have been made using any of the processes shown in FIG. 6, 7, 8, 9 or 10. A layer of black decorative ink 5 has been applied around the border of the sensor module. FIG. 13B shows the next step where busbar structures 23 are formed on top of the border ink 5 using a black conductive ink. A laser fusing process is then used to connect areas of the busbars 23 through the decorative ink 5 to the second TCL 3′ below. FIGS. 13C and 13D show a process which is similar to that shown in FIGS. 9 and 10. Laser beam 24 has the characteristics necessary to melt the busbar ink and displace the decorative ink so that an electrical connection 25 is made. So that the connection cannot be seen from the cover viewing side, it is necessary that the colour of the busbar ink fused into the via is exactly the same colour as the border decorative ink. This is most easily satisfied when both are black.

Other variations of the methods described above will be apparent to those skilled in the art without departing from the scope of the present invention (as defined in the claims). In particular, the features referred to above may be used in different combinations as required. Any of the features described above may, for example, be used with the features referred to in the claims independently of any other features described.

1. A method of fabricating a two-layer capacitive touch sensor panel comprising the following steps:
a) depositing a first transparent electrically conductive layer on a transparent cover sheet;
b) forming a first pattern in the first transparent electrically conductive layer to create a first set of discrete electrode structures therein;
c) depositing a transparent dielectric layer over the first discrete electrode structure of the first transparent electrically conductive layer;
d) depositing a second transparent electrically conductive layer onto the transparent dielectric layer;
e) forming a second pattern in the second transparent electrically conductive layer to create a second set of discrete electrode structures therein by laser ablation, the second pattern not penetrating or penetrating only part way through the dielectric layer so as not to damage the first set of discrete electrode structures;
f) forming electrical connections or vias between the first and second transparent electrically conductive layers through the dielectric layer; and
g) forming electrical connections between the first and/or second transparent electrically conductive layer and an electrical track or busbar formed at or adjacent the periphery of the panel.

2. The method of fabricating a two-layer capacitive touch sensor panel as claimed in claim 1, wherein said first pattern is also formed by laser ablation.

3. The method of fabricating a two-layer capacitive touch sensor panel as claimed in claim 1, wherein said forming of electrical connections or vias comprises the formation of holes though said dielectric layer by laser drilling.

4. The method of fabricating a two-layer capacitive touch sensor panel as claimed in claim 1, wherein said forming of electrical connections or vias comprises depositing a layer of laser beam absorbing material onto the first electrically conductive layer prior to deposition of the dielectric layer in step (c) and, following step (c), subjecting said material to laser irradiation so that parts thereof are heated, so they expand and become detached from the first electrically conductive layer dielectric layer leaving a hole in said dielectric layer.

5. The method of fabricating a two-layer capacitive touch sensor panel as claimed in claim 1, wherein said forming of electrical connections or vias comprises depositing a layer of laser beam absorbing material onto the dielectric layer prior to deposition of the second electrically conductive layer in step (d), subjecting said material to laser irradiation so that parts thereof are heated, so they expand and become detached from the dielectric layer leaving a hole in said dielectric layer.

6. The method of fabricating a two-layer capacitive touch sensor panel as claimed in claim 1, wherein, following steps (a), (c) and (d), said forming of electrical connections or vias comprises subjecting areas of the panel to laser irradiation such that the second electrically conductive layer, the dielectric layer and the first electrically conductive layer are melted whereby melted portions of the first and second electrically conductive layers contact each other through the dielectric layer.

7. The method of fabricating a two-layer capacitive touch sensor panel as claimed in claim 3 wherein a first layer of opaque material is deposited on the dielectric layer adjacent the edge of the panel and said laser drilling also forms holes through said opaque layer.

8. The method of fabricating a two-layer capacitive touch sensor panel as claimed in claim 3 wherein, during deposition of the second transparent electrically conductive layer in step (d), material of said second transparent electrically conductive layer is deposited into said holes so as to contact the first transparent electrically conductive layer.

9. The method of fabricating a two-layer capacitive touch sensor panel as claimed in claim 8 wherein a layer of opaque material is deposited over the second transparent electrically conductive layer in areas where it is deposited into said holes.

10. The method of fabricating a two-layer capacitive touch sensor panel as claimed in claim 9 wherein holes are formed through said layer of opaque material by laser drilling and an electrical connection formed between said electrical track or busbar and the second transparent electrically conductive layer through said holes.

11. The method of fabricating a two-layer capacitive touch sensor panel as claimed in claim 10 wherein said electrical connection includes opaque conductive material deposited into said holes.

12. The method of fabricating a two-layer capacitive touch sensor panel as claimed in claim 10 wherein said electrical connection includes melting a portion of the electrical track or busbar so that it contacts the second transparent electrically conductive layer through the layer of opaque material.

13. The method of fabricating a two-layer capacitive touch sensor panel as claimed in claim 2 wherein the patterning of the first and second transparent electrically conductive lays and the formation of electrical connections or vias through the dielectric layer are carried out using laser writing processes so avoiding the need to use lithographic process involving chemical etching and masks.

14. A two-layer capacitive touch sensor panel comprising:
a transparent cover sheet; a first transparent electrically conductive layer deposited on the transparent cover sheet;
a first pattern in the first transparent electrically conductive layer providing a first set of discrete electrode structures therein; a transparent dielectric layer deposited over the first discrete electrode structure of the first transparent electrically conductive layer;
a second transparent electrically conductive layer deposited onto the transparent dielectric layer;
a second pattern in the second transparent electrically conductive layer formed by laser ablation to create a second set of discrete electrode structures therein, the second pattern not penetrating or penetrating only part way through the dielectric layer so as not to damage the first set of discrete electrode structures;
electrical connections or vias between the first and second transparent electrically conductive layers through the dielectric layer; and
electrical connections between the first and/or second transparent electrically conductive layer and an electrical track or busbar formed at or adjacent the periphery of the panel.

15. The two-layer capacitive touch sensor panel as claimed in claim 14 wherein the first and second set of discrete electrode structures in the first and second transparent electrically conductive layers and the electrical connections or vias through the dielectric layer are formed by laser writing processes.

16. The two-layer capacitive touch sensor panel as claimed in claim 14, wherein the materials used to form the first and second transparent electrically conductive layers are selected such, for a given laser wavelength, that the energy density required to ablate the second transparent electrically conductive layer is significantly lower than that required to ablate the first transparent electrically conductive layer.

17. The two-layer capacitive touch sensor panel as claimed in claim 14, wherein the materials used to form the dielectric layer is selected such that it partially absorbs laser radiation passing therethrough such that, during manufacture, the energy density passing through the dielectric layer to the first transparent electrically conductive layer is attenuated to a level below the ablation energy density of the first transparent electrically conductive layer.

18. The two-layer capacitive touch sensor panel as claimed in claim 14, wherein the transparent dielectric layer has a thickness of 10 μm or less.

19. The two-layer capacitive touch sensor panel as claimed in claim 14, wherein the first and or second patterns comprise grooves having a width of 10 μm or less.
